(19) United States
(12) Patent Application Publication
(10) Pub. No.: US 2008/0003826 A1
(43) Pub. Date: Jan. 3, 2008

(54) METHOD FOR INCREASING THE PLANARITY OF A SURFACE TOPOGRAPHY IN A MICROSTRUCTURE

(76) Inventors: Thomas Werner, Reichenberg (DE); Robert Seidel, Dresden (DE); Frank Feustel, Dresden (DE)

Correspondence Address: WILLIAMS, MORGAN & AMERSON, 10333 RICHMOND, SUITE 1100, HOUSTON, TX, 77042, US

(21) Appl. No.: 11/674,869

(22) Filed: Feb. 14, 2007

(30) Foreign Application Priority Data
Jun. 30, 2006 (DE) 2006 030 265.6

(51) Int. Cl. H01L 21/302

(52) U.S. Cl. 438/689

(57) ABSTRACT

By additionally planarizing the surface topography of a planarization layer, which may be accomplished on the basis of mechanical contact, a uniform force, a polishing process and the like, an enhanced surface topography may be provided which may be advantageously used in subsequent patterning processes, such as photolithography, imprint techniques and the like.

### BACKGROUND OF THE INVENTION

1. Field of the Invention

Generally, the present disclosure relates to the manufacturing of microstructures, such as integrated circuits, and, more particularly, to planarization processes used during the patterning of specific levels of a microstructure for obtaining a substantially planar surface for subsequent processes.

2. Description of the Related Art

In manufacturing microstructures, such as integrated circuits, micromechanical devices, opto-electronic components and the like, device features such as circuit elements are typically formed on an appropriate substrate by patterning the surface portions of one or more material layers previously formed on the substrate. Since the dimensions, i.e., the length, width and height, of individual features are steadily decreasing to enhance performance and improve cost-effectiveness, these dimensions have to be maintained within tightly set tolerances in order to guarantee the required functionality of the complete device. Usually a large number of process steps have to be carried out for completing a microstructure, and thus the dimensions of the features during the various manufacturing stages have to be thoroughly monitored to maintain process quality and to avoid further cost-intensive process steps.

Device features are commonly formed by transferring a specified pattern from a photomask or reticle or an imprint die into an appropriate mask material, which, in the case of photolithography, represents a radiation-sensitive photoresist material, wherein the pattern transfer is accomplished by optical imaging systems with subsequent sophisticated resist treating and development procedures to obtain a resist mask having dimensions significantly less than the optical resolution of the imaging system.

Irrespective of the specific patterning process, it is frequently necessary to reduce any non-uniformities of the resulting surface topography of the microstructure in order to enhance the efficiency of a subsequent process step. In particular, optical lithography techniques are extremely sensitive to the underlying surface topography in advanced applications, since, with ever-decreasing feature sizes, the respective optical lithography tools are extremely complex and may also provide only reduced depth of focus and automatic alignment procedures, which may be sensitive to variations of the surface topography. For example, manufacturing metallization structures for highly advanced integrated circuits may typically require the formation of trenches and vias having lateral dimensions of 100 nm and even less, which have to be reliably formed in an appropriate dielectric material, which may then be filled with an appropriate conductive material, such as copper, copper alloy, silver, silver alloy and the like. A plurality of process strategies are currently practiced in order to form respective metallization structures, wherein the dielectric layer, which may already have a plurality of openings, is to be patterned again so as to modify existing openings or to produce further openings, such as trenches, which have to be precisely aligned to the previously formed openings. Due to the reduced dimensions of these openings, sophisticated lithography techniques requiring an improved surface topography have to be used. Consequently, so-called planarization layers are formed prior to the patterning process in order to provide a substantially planar surface topography, in order to enhance the subsequent lithography process. After the lithography process and possibly after any etch process, the corresponding planarization layer may be removed and the further processing may be continued on the basis of the resulting structure. Although the usage of planarization layers is highly efficient in many process stages during the fabrication of advanced microstructures, such as integrated circuits and the like, the continuous reduction of dimensions of microstructure features may nevertheless impose increasingly strict constraints on the patterning process so that even minor non-uniformities of the planarization layer may negatively affect subsequent process steps.

With reference to FIG. 1, a typical conventional process flow for forming a planarization layer will be described in order to discuss problems arising from the conventional technique. FIG. 1 schematically illustrates a cross-sectional view of a microstructure device 100 in an intermediate manufacturing stage, in which a pre-patterned surface topography has to be planarized for a subsequent process step. The microstructure device 100 may comprise a substrate 101, such as a semiconductor substrate as may typically be used for the formation of advanced integrated circuits and the like. The substrate 101 may have formed therein any microstructure features, such as circuit elements in the form of transistors, capacitors and the like, as required for the desired operational behavior of the device 100. For convenience, any such features within the substrate 101 are not shown. Furthermore, a patterned layer 102 is formed above the substrate 101, wherein, for instance, the patterned layer 102 may represent the dielectric material of a metallization layer of an integrated circuit. In this case, the material layer 102 may represent a dielectric material which may comprise, at least partially, a low-k dielectric material, i.e., a material having a relative permittivity of 3.0 or less, which may include a plurality of openings 102A that are to be filled with a metal or any other conductive material in a later manufacturing stage. For example, the openings 102A may represent via openings for conductive vias to be formed therein in order to provide electrical contact to any lower-lying contact regions in the substrate 101 and to respective metal regions or metal lines to be formed in the layer 102. Consequently, a further patterning process for the layer 102 may have to be performed, wherein the pronounced surface topography created by the openings 102A may not allow an appropriate optical patterning, in particular when highly advanced devices are considered, in which a lateral dimension of the respective openings 102A may be several hundred nanometers and even significantly less, such as 100 nm and less, as may be required in sophisticated integrated circuits having circuit elements of critical dimensions of 50 nm and even less. Furthermore, the device 100 may comprise a planarization layer 103, which may fill the openings 102A and may further cover exposed surface portions of the dielectric layer 102. The planarization layer 103 may be comprised of any appropriate material that enables a highly non-conformal deposition, and thus a reliable fill, while providing a substantially uniform surface topography. Moreover, the planarization layer 103 may preferably be comprised of any material that may be removed in a later stage with high selectivity with respect to the material of the layer 102.

A typical process flow for forming the microstructure device 100 as shown in FIG. 1 may comprise the following processes. After manufacturing any features, such as circuit elements and the like, within the substrate 101, i.e., in and above a respective semiconductor layer or any other appropriate material layer, the layer 102 may be formed by any appropriate deposition technique such as spin-on, chemical vapor deposition (CVD), physical vapor deposition (PVD) and the like. For instance, the layer 102 may represent a combined layer stack including conventional dielectrics and low-k dielectric materials, wherein any appropriate process sequence may be used, such as CVD in combination with spin-on techniques and the like. Thereafter, the layer 102 may be patterned so as to receive the openings 102A, which may be accomplished on the basis of established lithography techniques, such as photolithography, anisotropic etch techniques and the like. Next, the planarization layer 103 may be formed on the basis of an appropriate deposition technique, such as a spin-on process, wherein appropriate material, such as a polymer material, an inorganic material and the like, may be applied in a low viscous state so that the respective openings 102A may be reliably filled and a substantially uniform surface topography 103S is achieved. In other cases, other deposition techniques may be used, such as CVD, atomic layer deposition (ALD), immersion processes and the like, so as to apply the layer 103 in a highly non-conformal manner to obtain the substantially planar surface topography 103S. After the device 100 may have been subjected to an appropriate treatment, for instance for curing the material of the layer 103 or to stabilize the material by performing an out-gassing process in order to remove volatile solvents and the like, a certain degree of thickness variation may nevertheless be observed in the layer 103. For instance, the process of depositing the material of the layer 103 itself may be to a certain degree dependent on the underlying pattern of the layer 102 and/or the subsequent treatments for stabilizing or curing the material 103 may result in a pattern density dependent behavior. In the illustrated example, a reduced thickness may be obtained at an area 104, in which the density of the respective opening 102A is moderately high, while areas of a reduced pattern density may have a higher thickness.

After the application of the planarization layer 103, the further processing is continued, for instance by applying an appropriate resist material, which may then be patterned on the basis of sophisticated lithography techniques, wherein, however, the minor thickness variations may result in a corresponding variation of the resulting resist features due to inaccuracies of the exposure and/or alignment process. Consequently, a corresponding fluctuation of the respective device features may be obtained after patterning the layer 102 on the basis of the previously formed resist features. For instance, if respective metal trenches are to be formed within the layer 102, a respective degree of misalignment and a variation in metal line performance may be observed, which may reduce device performance and may also reduce production yield.

The present disclosure is directed to various methods that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to a technique that enables an enhanced planarization of surface topographies of microstructure devices on the basis of a planarization layer by performing an additional modification process for reducing non-uniformities of the planarization layer. For this purpose, a redistribution of material within the planarization layer and/or a selective removal of material thereof may be performed in order to reduce any height variations prior to performing subsequent process steps.

According to one illustrative embodiment disclosed herein, a method comprises forming a planarization layer above a substrate that comprises microstructure features, and selectively removing material of the planarization layer to reduce a non-uniformity in surface topography thereof. Furthermore, the method comprises performing a manufacturing process on the basis of the surface topography having the reduced non-uniformity and then removing the planarization layer.

In another illustrative embodiment, a method comprises forming a planarization layer above a substrate comprising microstructure features and redistributing material of the planarization layer when it is in a deformable state so as to reduce a non-uniformity of a surface topography of the planarization layer.

In yet another illustrative embodiment, a method comprises planarizing a surface topography of a microstructure comprising at least one opening by forming a planarization layer to fill the at least one opening and to provide excess material above the filled opening. Furthermore, material of the planarization layer is selectively removed from surface portions of increased height in order to reduce a non-uniformity of the surface topography. Furthermore, a lithography process is performed on the basis of the surface topography having the reduced non-uniformity.

### BRIEF DESCRIPTION OF THE DRAWINGS

The disclosure may be understood by reference to the following description taken in conjunction with the accompanying drawings, in which like reference numerals identify like elements, and in which:

FIG. 1 schematically illustrates a cross-sectional view of a microstructure device including a planarization layer formed in accordance with conventional process techniques;

FIGS. 2a-2d schematically illustrate cross-sectional views of a microstructure device during various manufacturing stages in forming a planarization layer of enhanced surface topography on the basis of a material removal according to illustrative embodiments disclosed herein;

FIGS. 3a-3d schematically illustrate cross-sectional views of a microstructure during various manufacturing stages for enhancing the planarity of a planarization layer according to further illustrative embodiments disclosed herein;

FIG. 3e schematically illustrates the application of a uniform force created by acceleration of respective substrates according to illustrative embodiments disclosed herein; and

FIG. 3f schematically illustrates a cross-sectional view of a microstructure device that is lithographically patterned on the basis of a planarization layer with enhanced surface topography according to illustrative embodiments disclosed herein.

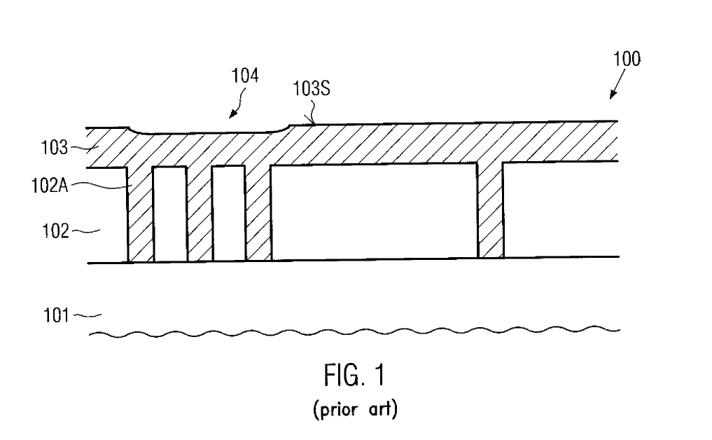

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the subject matter disclosed herein relates to enhancing the surface topography of a microstructure during intermediate manufacturing stages by providing a planarization layer and modifying the surface topography thereof prior to performing subsequent process steps based on the enhanced surface topography, wherein, in some illustrative embodiments, the subsequent process steps may include a lithographical patterning of the structure including the enhanced surface topography. Improving the surface topography of the planarization layer may be accomplished on the basis of a selective material removal, for instance by a polishing process, such as a chemical mechanical polishing (CMP) process, and/or by redistributing material within the planarization layer in order to remove or at least reduce surface non-uniformities. For this purpose, at least during the redistribution process of material, the planarization layer may be brought into a deformable state, in which an efficient equalization of the surface topography may be achieved. Thus, the subject matter disclosed herein is highly advantageous in the context of advanced microstructures, in which critical dimensions of respective features may be well below 100 nm, since here highly sophisticated lithography processes, for instance photolithography processes, advanced imprint techniques and the like, may be required wherein the process result may significantly depend on the initial surface topography. In one aspect, the manufacturing sequence of metallization structures of advanced semiconductor devices may be performed on the basis of a planarization layer having an advanced surface topography so that corresponding metallization features, such as vias and metal lines, may be efficiently patterned in a dielectric material that has already been pre-patterned so as to exhibit respective openings of lateral dimensions that may be several hundred nanometers and significantly less, such as 100 nm and less. Consequently, a significantly reduced dependency on the locally varying pattern density of the previously patterned material layers, such as the dielectric of metallization structures, during the formation of a planarization layer, may be accomplished which may thus directly translate into an enhanced device performance and reduced yield loss. Consequently, the subject matter disclosed herein is especially advantageous in the context of highly scaled microstructures, such as modern CPUs, memory chips, ASICs (application specific ICs), other optoelectronic devices, micromechanical devices and the like, since here respective lithography processes are particularly sensitive to variations in topography. It should be understood, however, that the principles of the subject matter disclosed herein may also be applied to less critical applications, thereby providing enhanced process uniformity and device performance. Hence, the present invention should not be considered as being restricted to specific device dimensions and microstructure types, unless such restrictions are explicitly set forth in the specification or the appended claims.

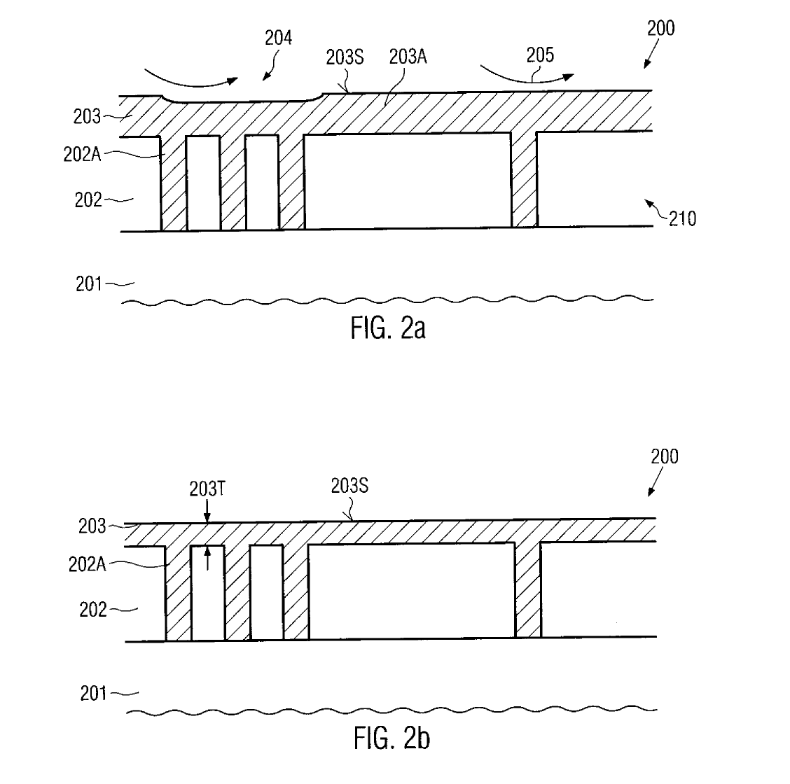

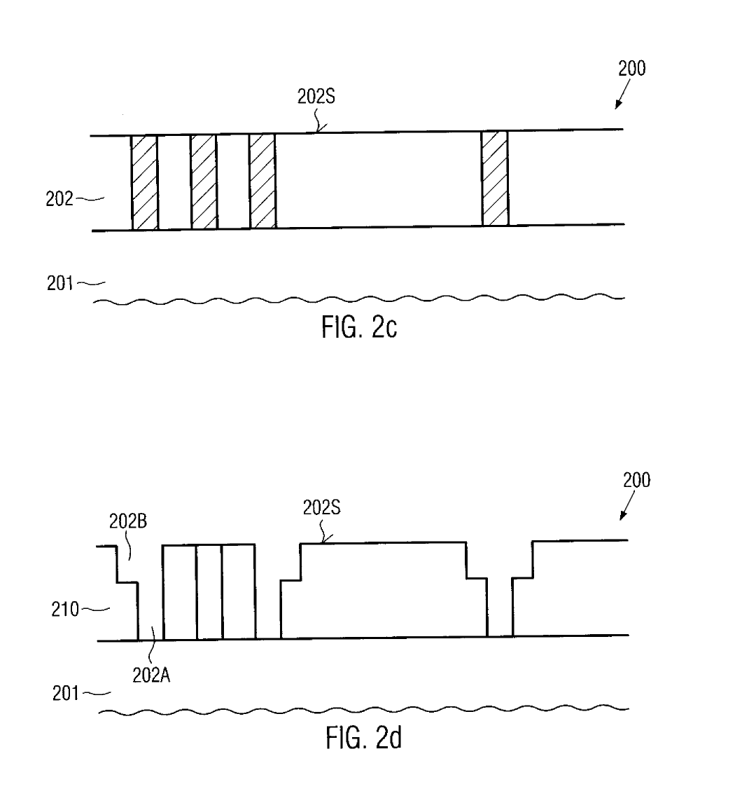

FIG. 2a schematically illustrates a cross-sectional view of a microstructure device 200 during an intermediate manufacturing stage. The device 200 may comprise a substrate 201 which may represent any appropriate substrate for forming therein and thereon respective features, such as circuit elements in the form of transistors, capacitors, resistors and the like, or any other micromechanical or optoelectronic devices. For convenience, any such microstructure features are not shown in FIG. 2a. Furthermore, a layer 210 is formed above the substrate 201, wherein the layer 210 may, in one illustrative embodiment, represent a metallization layer of a metallization structure for an advanced semiconductor device, which may include in a respective device layer (not shown) formed above the substrate 201 circuit elements having critical dimensions of approximately 100 nm and less, or even 50 nm and less. For instance, field effect transistor elements may be formed in the respective device layer having a gate length in the above-identified range of magnitude. The layer 210 may comprise a dielectric material in the form of a respective dielectric layer 202, wherein, in this manufacturing stage, other materials may also be provided in the layer 210. In the above-discussed example of a metallization layer, low-k dielectric material may be provided in order to reduce the relative permittivity of the respective metallization structures to be formed in the layer 210. In other illustrative embodiments, the dielectric layer 202 provided in this manufacturing stage may represent any appropriate material that may have to be patterned in a subsequent process stage. For instance, the dielectric material of the layer 202 may represent a sacrificial material, at least partially, which may be removed after the formation of respective metal structures therein. The layer 202 may have formed therein respective openings 202A having an appropriate size and dimensions as required by the design rules. Furthermore, the pattern density of the openings 202A across the substrate 201 may significantly vary, as is previously explained. For instance, the openings 202A may represent via openings and/or trenches for the layer 210, when representing a metallization layer. The lateral dimension as well as the extension thereof in the height, i.e. thickness, direction may depend on the device requirements and may be in the range of several hundred nanometers and significantly less. Furthermore, in this manufacturing stage, a planarization layer 203 comprised of any appropriate material, such as inorganic materials, organic materials such as polymer materials and the like, may be provided so as to fill the openings 202A and further provide excess material 203A above the filled openings 202A and non-patterned portions of the dielectric layer 202. As previously explained, in this manufacturing stage, a surface topography 203S of the layer 203 may vary due to a non-constant pattern density, non-uniformities of the deposition process and/or of any post-deposition processes and the like.

The microstructure device 200 as shown in FIG. 2a may be formed on the basis of the following processes. After the formation of any microstructure features, such as circuit elements and the like, if provided, in and above the substrate 201, the dielectric layer 202, which may comprise one or more sub-layers, may be formed on the basis of any appropriate deposition techniques. For example, an appropriate layer stack which may include a low-k dielectric material, when sophisticated applications of semiconductor device are considered, may be formed on the basis of well-established recipes, which may include spin-on techniques, CVD techniques and the like. In some illustrative embodiments, the respective dielectric layer stack may comprise any appropriate material that may act as an anti-reflective coating (ARC) layer, a hard mask layer and the like, as is required for the subsequent patterning of the openings 202A. For instance, an appropriate resist mask may be formed on the basis of advanced photolithography techniques, followed by anisotropic etch recipes so as to form the openings 202A on the basis of the resist mask. It should be appreciated that this patterning process may also include the formation of an appropriate hard mask prior to actually etching into lower-lying portions of the dielectric layer 202. In other illustrative embodiments, a respective resist mask may be formed on the basis of advanced imprint techniques, wherein a moldable resist material or any other polymer material may be patterned by imprinting an appropriate die into the moldable material that is in a high deformable state and removing the die when the moldable material is in a non-deformable state. In still other illustrative embodiments, the dielectric layer 202 may be provided as a moldable material, which may be directly patterned on the basis of an imprint technique, as described above. After the patterning of the dielectric layer 202, the planarization layer 203 may be formed on the basis of any appropriate deposition technique, as is also described with reference to the layer 103, in order to fill the openings 202A for providing the substantially planar surface topography 203S.

As previously explained, any non-uniformities of the topography 203S may be reduced by appropriately treating the layer 203, which, in one illustrative embodiment, is accomplished by selectively removing material on the basis of a polishing process 205, such as a CMP process, on the basis of appropriately selected process parameters. It should be appreciated that corresponding process parameters, such as relative speed between a polishing pad (not shown) and the substrate 201, a down force applied during the polishing process, the type of slurry supplied and the like, may be readily established on the basis of respective test runs, wherein appropriate parameters for a specified pre-treatment of the layer 203 prior to the process 205 may also be established. That is, after the deposition of the planarization layer 203, a respective treatment, such as curing, heat treating and the like, may be performed in order to establish the material characteristics as required in the subsequent process steps, such as a subsequent lithography process. By respective test runs for determining parameter value ranges for the polishing process 205, appropriate parameters for the pre-treatment may also be identified such that the material characteristics may meet the requirements of the polishing process and of the subsequent processes, such as a lithography process. Thus, by means of the polishing process 205, a significant reduction of any non-uniformities of the surface topography 203S may be achieved by selectively removing material of the layer 203.

FIG. 2b schematically illustrates the microstructure device 200 after the process 205, thereby providing the layer 203 with a reduced thickness 203T. Moreover, due to the selective material removal, the thickness 203T may exhibit a significantly reduced variation compared to the initial thickness of the layer 203 as shown in FIG. 2a, thereby establishing the surface topography 203S with a significantly reduced non-uniformity.

FIG. 2c schematically illustrates the semiconductor device 200 in accordance with a further illustrative embodiment, in which the polishing process 205 may be continued in order to expose non-patterned portions of the underlying dielectric layer 202. As shown, surface portions 202S of the layer 202 are exposed, while the respective openings 202A are still reliably filled by the residues of the planarization layer 203. In some illustrative embodiments, the material of the layer 203 or a respective pre-polish treatment may be selected such that mechanical characteristics or any other characteristic, such as optical or chemical characteristics, of the layer 203 may be obtained that may significantly differ from the respective characteristics of the layer 202, thereby providing an efficient means for controlling the polishing process 205. Hence, upon exposure of the surface portions 202S, a respective endpoint detection signal may be obtained on the basis of the difference in the material characteristics. For this purpose, in some embodiments, a difference in the polishing behavior may be detected, when the materials of the layers 202 and 203 have significantly different mechanical characteristics. In other cases, when appropriate optical endpoint detection means are provided in the corresponding polishing tool, a difference of optical characteristics of the layers 202 and 203 may be used in order to reliably stop the polishing process 205. In still further embodiments, the chemical ambient of the polishing process may be monitored for identifying the exposure of the surface portions 202S.

Consequently, the surface topography 203S may be significantly enhanced, irrespective of whether a remaining material layer is formed above the dielectric layer 202 or the corresponding surface portions 202S are exposed during the mechanical material removal process 205. Thereafter, an appropriate mask layer may be formed above the enhanced surface topography 203S, for instance by providing an appropriate resist material, possibly in combination with any appropriate ARC layers, in order to pattern the resist material on the basis of photolithography techniques, as previously described. Due to the enhanced surface topography 203S, respective exposure and/or alignment non-uniformities may be significantly reduced. Thereafter, the layer 202 may be further patterned on the basis of the corresponding mask layer formed thereabove. For instance, respective trenches may be formed in the upper portion of the layer 202, wherein, after removal of the planarization layer 203, the corresponding openings 202A and further trenches may be filled with a highly conductive material to form respective metallization structures of the metallization layer 210.

In other illustrative embodiments, the patterning of the dielectric layer 202 may be accomplished on the basis of an advanced imprint technique, in which a moldable polymer or resist material may be formed above the enhanced surface topography 203S, which may then be appropriately patterned, as is previously described. Thereafter, a corresponding etch process may be performed to obtain the required trenches or other openings in the dielectric layer 202. Thereafter, the resist or polymer material may be removed along with the planarization layer 203.

FIG. 2d schematically illustrates the device 200 after the removal of the planarization layer 203 and with additional openings 202B formed in the layer 210. Thereafter, respective metal regions may be formed in the openings 202A, 202B, when the layer 210 represents a metallization layer, as described above.

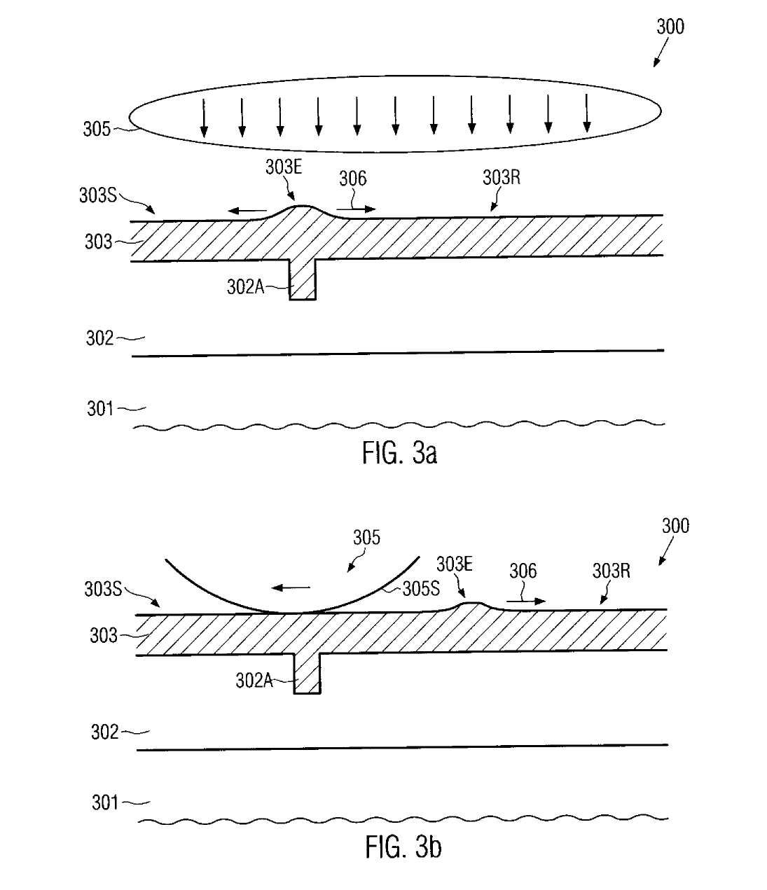

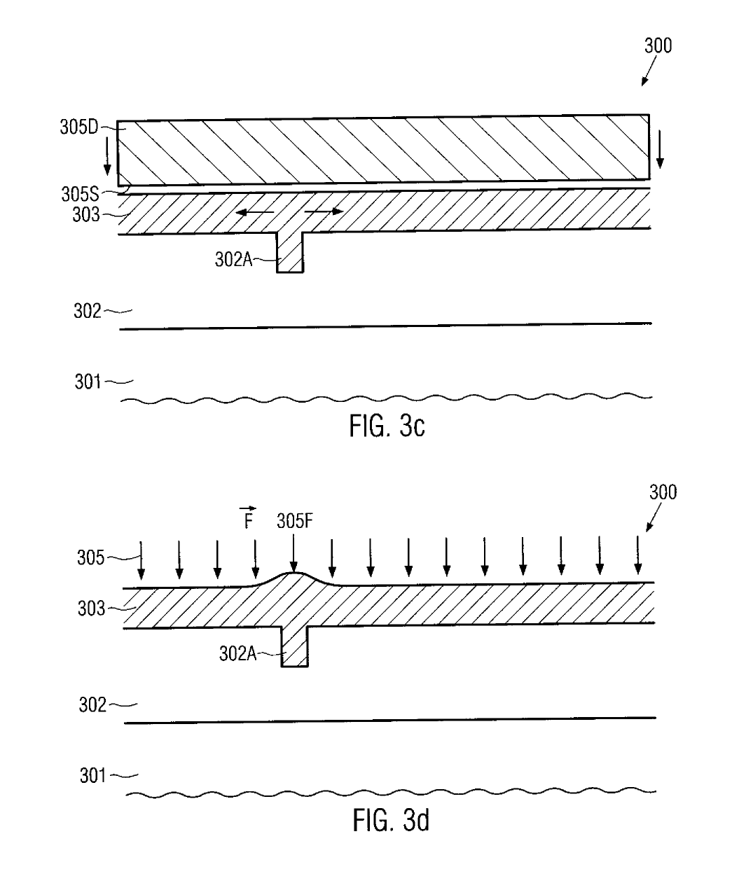

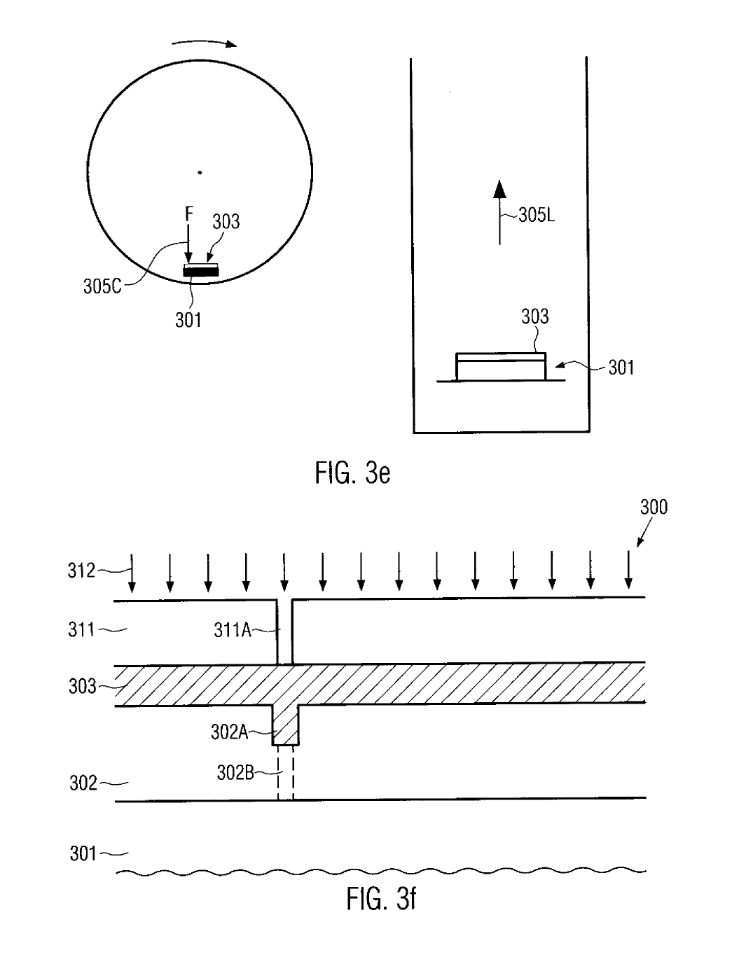

With reference to FIGS. 3a-3f, further illustrative embodiments will now be described in more detail, wherein, additionally or alternatively to the techniques described above, a redistribution of material within a planarization layer may be provided in order to enhance the surface topography thereof.

FIG. 3a schematically illustrates a microstructure device 300 comprising a substrate 301 having formed thereabove a material layer 302, which may include an opening 302A. With respect to the substrate 301, the same criteria apply as previously explained with reference to the substrate 201. Similarly, the material layer 302 may represent any material layer having a pronounced surface topography, for instance caused by one or more of the openings 302A, which may need to be planarized during the further manufacturing phase for completing the device 300. In some illustrative embodiments, the layer 302 may represent a dielectric material for forming a metallization structure, while in other embodiments the layer 302 may represent any type of patterned material layer which may represent an intermediate manufacturing stage of any microstructure device. Furthermore, a planarization layer 303 is formed on the layer 302 in order to provide a substantially planar surface, which may nevertheless exhibit a specific non-uniformity, as previously explained. For instance, an area 303E of increased thickness may have been created during the deposition of the layer 303 and/or during a subsequent treatment for adjusting material characteristics of the layer 303.

The device 300 as shown in FIG. 3a may be formed on the basis of any process techniques, as previously described with reference to the devices 100 and 200. Moreover, the device 300 is subjected to a material redistribution process 305 in order to selectively distribute material from portions of enhanced thickness 303E to portions of reduced thickness 303R as indicated by the arrows 306. It should be appreciated that the redistribution may not necessarily be symmetric with respect to the surrounding areas of reduced thickness 303R, but the redistribution may also occur in a highly asymmetric manner. For instance, the redistribution may mainly occur in one of the lateral directions shown in FIG. 3a. For an efficient material redistribution, the process 305 may create a respective lateral force component, which is directed along the direction as indicated by at least one of the arrows 306, when the planarization layer 303 is in a deformable state in order to initiate the desired redistribution and thus equalization of the resulting surface topography 303S. For instance, a corresponding laterally acting force may be obtained by gravity, when the substrate 301 is substantially horizontally oriented, wherein the viscosity of the material of the layer 303 may be reduced sufficiently in order to allow a corresponding material redistribution. In some illustrative embodiments, the process 305 may include a corresponding surface treatment in order to reduce the surface tension of the material 303 in its highly deformable state in order to allow an appropriate material redistribution by gravity. Thereafter, the material of the planarization layer 303 may be brought into a highly non-deformable state, when a subsequent process step requires an increased hardness of the planarization layer 303.

In other illustrative embodiments, the material of the layer 303 may be applied in a low viscous state and may be maintained in this state until the process 305 is completed. In other illustrative embodiments, the planarization layer 303 as deposited may be subjected to any desired post-deposition treatment, such as out-gassing of solvents and the like, and may afterwards be brought into a deformable state by a respective treatment in order to allow the material redistribution during the process 305. In this case, the process 305 may include respective steps for transiting the material 303 into the deformable state and maintaining the deformable state as long as a specific material redistribution is desired. The respective creation of the deformable state may in some illustrative embodiments be restricted to a defined portion of the device 300 so as to also restrict a corresponding material redistribution to a well-defined area, while other areas may be maintained in a substantially non-deformable state, thereby providing a “near distance” effect of the process 305. For instance, a portion treated by the process 305 may be immediately subjected to a corresponding treatment, such as cooling, radiation hardening and the like, in order to “freeze” the previously obtained highly uniform surface topography in the treated portion. This may be accomplished by scanning a spatially confined ambient of the process 305 across the substrate 301, either step-wise or continuously, in order to locally restrict or modify the surface topography of the layer 303. For example, a locally restricted heat treatment, for instance on the basis of radiation, a heated fluid and the like, may be scanned across the substrate 301 thereby providing the required local deformable state of the material of the layer 303, wherein, in addition to the gravitational force, possibly in combination with surface reactants, pressure may be applied for instance by a fluid such as a heated gas stream, which may cause, due to a scan motion, a respective material redistribution.

FIG. 3b schematically illustrates the device 300 when subjected to the redistribution process 305 according to further illustrative embodiments. In this embodiment, a deforming surface 305S may be brought into mechanical contact with the planarization layer 303 during the process 305, wherein the deforming surface 305S may be applied as a curved surface, for instance provided by a die roll, which may be rolled across the surface of the layer 303, thereby redistributing the material of the layer 303. For this purpose, a relative motion between the substrate 301 and the surface 305S may be established such that the relative distance between the substrate 301 and the surface 305S may be maintained substantially constant so as to provide a highly uniform thickness across the entire substrate 301. Depending on the radius of curvature of the surface 305S, which may have a defined dimension perpendicular to the drawing plane of FIG. 3b, a more or less amount of the layer 303 may be simultaneously contacted along the direction of relative motion. Moreover, in some cases, the deforming surface 305S may concurrently provide respective surface conditions for locally bringing the material 303 into its highly deformable state. For instance, the surface 305S may be appropriately heated in order to reduce the viscosity upon contact with the material 303. Moreover, depending on the material characteristics and the underlying structure components of the device 300, a down force exerted by the surface 305S may be selected in accordance with process requirements.

FIG. 3c schematically illustrates the device 300 subjected to the redistribution process 305 based on a deforming surface 305S having a high degree of planarity over an extended area. For example, the planar deforming surface 305S may be provided in the form of a respective die or stamp 305D that may be brought into contact with the layer 303 during the process 305. That is, the process 305 in this illustrative embodiment may be considered as an imprint technique with a non-patterned imprint die and with an appropriately selected down force so as to enable adaptation of the layer 303 in its deformable state to the highly planar deforming surface 305S. For this purpose, corresponding process tools as are also used for imprint lithography may also be efficiently used for reducing the non-uniformity of the planarization layer 303.

FIG. 3d schematically illustrates the device 300 wherein, during the process 305, a substantially uniform force 305F is exerted in a substantially perpendicular direction when the layer 303 is in a highly deformable state in order to promote the material redistribution therein. For example, a uniform electrical force or magnetic force may be applied when the material of the layer 303 is responsive to a corresponding force. In other illustrative embodiments, the force 305F may be obtained by acceleration of the substrate 301, thereby enabling a precise adjustment of the magnitude of the force 305F for any type of material used for the planarization layer 303.

FIG. 3e schematically illustrates two types of forces created by accelerating the substrate 301 when the layer 303 is in a highly deformable state. For instance, the substrate 301 may be subjected to a rotational motion, thereby exerting a centrifugal force 305C on the layer 303. Consequently, by controlling the rotational speed, the magnitude of the force 305C may be adjusted for a given radius of the respective rotational motion. In other illustrative embodiments, the substrate 301 may be subjected to a linear acceleration 305L in order to create a respective force, which may also be precisely controlled on the basis of the respective acceleration conditions. Consequently, an efficient material redistribution may be accomplished, wherein the process 305 as shown in FIG. 3e may be used for treating a plurality of substrates concurrently, while, in other situations, only portions of the respective substrate 301 may be treated, for instance by locally heating the substrate 301 while exerting the respective forces 305C, 305L. For instance, using the linear acceleration 305L, an arbitrary number of substrates may be processed with a high degree of uniformity of the resulting equalizing force across the individual substrates and across the entire number of substrates.

FIG. 3f schematically illustrates the microstructure device 300 in a further advanced manufacturing stage. Here, a mask layer 311 may be formed above the planarization layer 303 having the enhanced surface topography 303S, wherein the mask layer 311 may be appropriately patterned in order to allow a further patterning of the layer 302. For instance, based on a respective opening 311A, a corresponding opening 302B may be formed in the layer 302 within the previously patterned opening 302A. It should be appreciated, however, that any other patterning regime may be used, depending on the device requirements.

The mask layer 311 may be formed on the basis of any appropriate lithography technique, such as photolithography, imprint lithography and the like, as is previously explained. Thereafter, the device 300 may be subjected to an anisotropic etch process 312 in order to pattern the layer 302, in combination with the planarization layer 303. Thereafter, the mask layer 311 and the planarization layer 303 may be removed and the further processing of the device 300 may be continued in accordance with process and device requirements.

As a result, the subject matter disclosed herein provides a technique for significantly enhancing the uniformity of a surface topography of a planarization layer by selectively removing material thereof, for instance on the basis of a polishing process, and/or by redistributing material within the planarization layer by bringing it, at least temporarily, and possibly in a locally restricted manner, into a highly deformable state so as to create a respective lateral force for initiating the redistribution effect. In some illustrative embodiments, this may be accomplished on the basis of mechanically contacting the planarizing layer in its highly deformable state by an appropriately designed deforming surface, while, in other cases, a uniform force, which substantially acts perpendicularly on the planarization layer, may be provided. Consequently, further process steps such as lithographical patterning processes may be performed on the basis of a highly uniform surface topography, thereby increasing process efficiency and reducing non-uniformities of microstructural features.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a planarization layer above a dielectric layer of a metallization structure formed above a substrate;
selectively removing material of said planarization layer to reduce a non-uniformity in surface topography;
performing a manufacturing process on the basis of said surface topography having the reduced non-uniformity; and
removing said planarization layer.

2. The method of claim 1, wherein forming said planarization layer comprises filling at least one of a via opening and a trench formed in said dielectric layer.

3. The method of claim 2, wherein material of said planarization layer is removed so as to maintain a residual layer on said dielectric layer and said filled at least one of a via opening and a trench.

4. The method of claim 2, wherein material of said planarization layer is removed so as to expose said dielectric layer.

5. The method of claim 4, wherein a process of removing said material of said planarization layer is controlled by endpoint detection on the basis of exposed surface portions of said dielectric layer.

6. The method of claim 1, wherein selectively removing material comprises performing a chemical mechanical polishing process.

7. A method, comprising:
forming a planarization layer above a substrate comprising microstructure features; and
redistributing material of said planarization layer during a deformable state thereof so as to reduce a non-uniformity of a surface topography of said planarization layer.

8. The method of claim 7, wherein redistributing material comprises mechanically contacting said layer by a deforming surface.

9. The method of claim 8, wherein said deforming surface is provided by a die roll.

10. The method of claim 8, wherein said deforming surface is provided by a die having a planar contact surface.

11. The method of claim 7, wherein redistributing material comprises applying a uniform force created by accelerating said substrate.

12. The method of claim 11, wherein said planarization layer is formed in a deformable state and is maintained in the deformable state while applying said force.

13. The method of claim 7, wherein said planarization layer is brought into said deformable state after forming said planarization layer.

14. The method of claim 13, wherein said deformable state is generated upon applying a pressure.

15. The method of claim 7, wherein forming said planarization layer comprises filling an opening formed in a material layer formed above said substrate.

16. The method of claim 15, wherein said opening represents an opening of a metallization structure.

17. A method, comprising:
planarizing a surface topography of a microstructure comprising at least one opening by forming a planarization layer to fill said at least one opening and to provide excess material above said filled opening;
selectively removing material of said planarization layer from surface portions of increased height to reduce a non-uniformity of said surface topography, and
performing a lithography process on the basis of said surface topography of reduced non-uniformity.

18. The method of claim 17, wherein selectively removing material of said planarization layer comprises redistributing material within said planarization layer.

19. The method of claim 18, wherein redistributing material within said planarization layer comprises applying additional pressure to said planarization layer in a deformable state thereof.

20. The method of claim 17, wherein selectively removing material comprises performing a polishing process.
